(19) United States
(12) Patent Application Publication
(10) Pub. No.: US 2026/0165015 A1
(43) Pub. Date: Jun. 11, 2026

(54) DISPLAY PANEL, DISPLAY APPARATUS AND MASK

(71) Applicants: Wuhan Tianma Microelectronics Co., Ltd., Wuhan (CN); Wuhan Tianma Microelectronics Co., Ltd. Shanghai Branch, Shanghai (CN)

(72) Inventors: Yu Xin, Wuhan (CN); Yuantao Wu, Shanghai (CN)

(73) Assignees: Wuhan Tianma Microelectronics Co., Ltd., Wuhan (CN); Wuhan Tianma Microelectronics Co., Ltd. Shanghai Branch, Shanghai (CN)

(21) Appl. No.: 19/538,003

(22) Filed: Feb. 12, 2026

Related U.S. Application Data
(63) Continuation of application No. 17/830,192, filed on Jun. 1, 2022.

(30) Foreign Application Priority Data
Dec. 7, 2021 (CN) 202111485647.4

(51) Int. Cl. H10K 59/88; H10K 59/12; H10K 59/35

(52) U.S. Cl. CPC H10K 59/88; H10K 59/351; H10K 59/12

(57) ABSTRACT

A display panel, a display apparatus and a mask are provided. The display panel includes a substrate, first dummy sub-pixels and regular sub-pixels. The display panel has a display region and a non-display region, and the non-display region has an electrode contact region. The display panel includes a substrate, and first dummy sub-pixels and regular sub-pixels located at a same side of the substrate. At least a part of the first dummy sub-pixels overlaps with the electrode contact region in a direction perpendicular to the substrate. The regular sub-pixels are located in the display region and includes first-color sub-pixels, and the first-color sub-pixels each include a first light-emitting material layer. The first dummy sub-pixels have a same material as the first light-emitting material layer.

### CROSS-REFERENCE TO RELATED APPLICATION

This application is a continuation of U.S. patent application Ser. No. 17/830,192, filed on Jun. 1, 2022, which claims to the benefit of Chinese Patent Application No. 202111485647.4, filed on Dec. 7, 2021, the content of which is incorporated herein by reference in its entirety.

### TECHNICAL FIELD

The present disclosure relates to the field of display technologies and, particularly, relates to a display panel, a display apparatus, and a mask.

### BACKGROUND

As a display technology, organic light-emitting diode (OLED) has advantages of fast response, high brightness, high contrast, low power consumption, and flexibility. At present, some display products have cyan or pink edges in a display region during display operation. A display failure rate for this phenomenon is about 10%, which adversely affects the display quality of products and the yield of production lines.

### SUMMARY

The present disclosure provides a display panel, a display apparatus, and a mask to address display unevenness at an edge of a display region in the related art.

In a first aspect of the present disclosure, a display panel is provided. In an embodiment, the display panel comprises a display region and a non-display region, and the non-display region comprises an electrode contact region. In an embodiment, the display panel includes a substrate, and first dummy sub-pixels and regular sub-pixels located at a same side of the substrate. In an embodiment, at least a part of the first dummy sub-pixels overlaps with the electrode contact region in a direction perpendicular to the substrate. In an embodiment, the regular sub-pixels are located in the display region and includes first-color sub-pixels, and the first-color sub-pixels each include a first light-emitting material layer. In an embodiment, the first dummy sub-pixels comprise a same material as the first light-emitting material layer.

In a second aspect of the present disclosure, a display apparatus is provided. In an embodiment, the display apparatus includes a display panel comprising a display region and a non-display region, and the non-display region comprises an electrode contact region. In an embodiment, the display panel includes a substrate, and first dummy sub-pixels and regular sub-pixels located at a same side of the substrate. In an embodiment, at least a part of the first dummy sub-pixels overlaps with the electrode contact region in a direction perpendicular to the substrate. In an embodiment, the regular sub-pixels are located in the display region and includes first-color sub-pixels, and the first-color sub-pixels each include a first light-emitting material layer. In an embodiment, the first dummy sub-pixels comprise a same material as the first light-emitting material layer.

In a third aspect of the present disclosure, a mask for manufacturing sub-pixels in a display panel is provided. In an embodiment, the display panel comprises a display region and a non-display region, the non-display region comprises an electrode contact region; the sub-pixels include regular sub-pixels located in the display region and dummy sub-pixels at least partially located in the non-display region. In an embodiment, the display panel includes a substrate, at least a part of the dummy sub-pixels overlaps with the electrode contact region in a direction perpendicular to the substrate. In an embodiment, the mask includes sub-regions, each of the sub-regions including a pixel evaporation region and a dummy evaporation region; and the pixel evaporation region includes pixel openings, and the dummy evaporation region includes dummy openings. In a thickness direction of the mask, the dummy openings are full-etched openings penetrating through the mask. In an embodiment, the pixel openings are configured to correspond to a regular sub-pixel region to evaporate a light-emitting material layer of the regular sub-pixels in an evaporation process. In an embodiment, the dummy openings are configured to correspond to a dummy sub-pixel region to evaporate the dummy sub-pixels in the evaporation process.

### BRIEF DESCRIPTION OF DRAWINGS

In order to better illustrate technical solutions of embodiments of the present disclosure or technical solutions of the related art, the accompanying drawings used in embodiments or the related art are briefly described below. The drawings described below are merely a part of the embodiments of the present disclosure. Based on these drawings, those skilled in the art can obtain other drawings.

FIG. 1 is a partial schematic diagram of a display panel according to an embodiment of the present disclosure.

FIG. 2 is a cross-sectional view at a line A-A′ shown in FIG. 1 according to an embodiment of the present disclosure.

FIG. 3 is a partial schematic diagram of a display panel according to another embodiment of the present disclosure.

FIG. 4 is a partial schematic diagram of a mask according to an embodiment of the present disclosure.

FIG. 5 is a partial schematic diagram of a mask according to another embodiment of the present disclosure.

FIG. 6 is a partial schematic diagram of a mask according to another embodiment of the present disclosure.

FIG. 7 is a schematic diagram showing alignment of the mask with a substrate to be evaporated according to an embodiment of the present disclosure.

FIG. 8 is a partial schematic diagram of an electrode contact region of a display panel according to another embodiment of the present disclosure.

FIG. 9 is a cross-sectional view at a line B-B′ in FIG. 8 according to an embodiment of the present disclosure.

FIG. 10 is a partial schematic diagram of a contact metal layer of a display panel according to another embodiment of the present disclosure.

FIG. 11 is a partial schematic diagram of an electrode contact region of a display panel according to another embodiment of the present disclosure.

FIG. 12 is a cross-sectional view at a line C-C′ in FIG. 11 according to another embodiment of the present disclosure.

FIG. 13 is a partial schematic diagram of a display panel according to another embodiment of the present disclosure.

FIG. 14 is a partial schematic diagram of a display panel according to another embodiment of the present disclosure.

FIG. 15 is a cross-sectional view at a line D-D′ in FIG. 14 according to an embodiment of the present disclosure.

FIG. 16 is a partial schematic diagram of an electrode contact region in a display panel according to another embodiment of the present disclosure.

FIG. 17 is a cross-sectional view at a line E-E′ in FIG. 16 according to an embodiment of the present disclosure.

FIG. 18 is a partial schematic diagram of a display panel according to another embodiment of the present disclosure.

FIG. 19 is a cross-sectional view at a line F-F′ in FIG. 18 according to an embodiment of the present disclosure.

FIG. 20 is a cross-sectional view at a line F-F′ in FIG. 18 according to another embodiment of the present disclosure.

FIG. 21 is a top view of a display panel according to another embodiment of the present disclosure.

FIG. 22 is a top view of a display panel according to another embodiment of the present disclosure.

FIG. 23 is a cross-sectional view at a line G-G′ in FIG. 22 according to an embodiment of the present disclosure.

FIG. 24 is a schematic diagram of a display apparatus according to an embodiment of the present disclosure.

### DESCRIPTION OF EMBODIMENTS

In order to more clearly illustrate objects, technical solutions and advantages of embodiments of the present disclosure, the technical solutions in embodiments of the present disclosure are clearly and completely described below with reference to the accompanying drawings. The described embodiments are merely part of the embodiments of the present disclosure rather than all of the embodiments. All other embodiments obtained by those skilled in the art shall fall into the scope of the present disclosure.

The terms used in the embodiments of the present disclosure are merely for the purpose of describing specific embodiment, rather than limiting the present disclosure. The terms “a,” “an,” “the,” and “said” in a singular form in the embodiments of the present disclosure and the attached claims are also intended to include plural forms thereof, unless noted otherwise.

Conventional displays are uneven at an edge of a display region. In this regard, it is found that cyan or pink edges of the display region occur on profiled display products, especially products having a round shape. In organic self-luminous display products, it is conventional to use a mask to evaporate the light-emitting material layer in the sub-pixels. For profiled products, the design of openings of a high-precision mask adapt the shape of the display region of the profiled product, and the opening pattern of the mask defines an arc abrupt change at a position corresponding to the edge of the display region. When the high-precision mask is bonded to the substrate to be evaporated in an evaporation chamber, the arc abrupt change at the position corresponding to the edge of the display region may adversely affect bonding between the mask and the substrate to be evaporated, resulting in a large gap between the high-precision mask and the substrate to be evaporated after being bonded. Moreover, a poor bond between the mask and the substrate to be evaporated causes a larger shadow region of the evaporated light-emitting material layer at the edge of the display region. In particular, the thicker the evaporated film layer, the larger the shadow of evaporation, and the narrower the effective film layer width, thereby leading to a color cast at the edge of the display region. The effective film layer width refers to a width of an organic layer evaporated in the opening of a pixel definition layer, and can be measured in a cross section of the display panel.

In order to address the above technical problems, an aspect of the present disclosure provides a display panel. When a process for evaporating the light-emitting material layer of the sub-pixel is designed, the evaporated edge is externally expanded to periphery of a display region, so that the final evaporated light-emitting material layer with a larger shadow region is located at the periphery of the display region due to the poor bonding between the mask and the substrate to be evaporated caused by the abrupt change at the edge of pattern of a mask, and the yield of the organic layer evaporated near the edge of the display region is achieved, thereby reducing the display unevenness caused by the display color cast due to poor bonding of the mask, and improving the display quality of products and the yield of production lines.

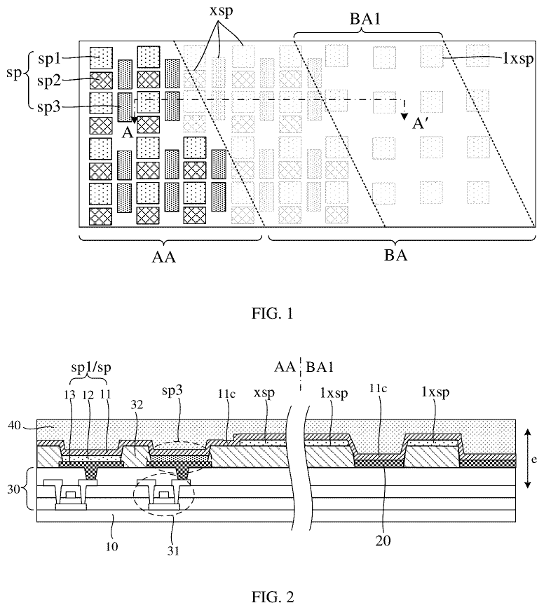

FIG. 1 is a partial schematic diagram of a display panel according to an embodiment of the present disclosure, and FIG. 2 is a cross-sectional view at a line A-A′ shown in FIG. 1 according to an embodiment of the present disclosure.

Referring to exemplary embodiments illustrated in FIG. 1 and FIG. 2, the display panel has a display region AA and a non-display region BA. The non-display region BA includes an electrode contact region BA1. The display region AA includes a plurality of regular sub-pixels sp. The regular sub-pixel sp includes a first electrode 11, a light-emitting layer 12, and a second electrode 13 that are stacked on one another. The first electrode 11 is located at a side of the second electrode 13 away from a substrate 10. The first electrodes 11 of the respective regular sub-pixels sp are connected to each other to form an electrode layer 11c. According to the embodiment shown in FIG. 1, the regular sub-pixel sp includes a first-color sub-pixel sp1, a second-color sub-pixel sp2, and a third-color sub-pixel sp3. Each of the first-color sub-pixel sp1, the second-color sub-pixel sp2, and the third-color sub-pixel sp3 is one of a red sub-pixel, a green sub-pixel, and a blue sub-pixel. It should be noted that, the arrangement of the respective color sub-pixels in FIG. 1 is only a schematic illustration, which does not constitute any limitation to the present disclosure.

According to the embodiment shown in FIG. 2, the electrode layer 11c extends beyond the display region AA and is connected to the contact metal layer 20 in the electrode contact region BA1. The electrode layer 11c provides a voltage signal to the electrode layer 11c through the contact metal layer 20. The electrode contact region BA1 can be understood as a region where there is electrical contact between the electrode layer 11c at the periphery of the display region AA and the contact metal layer 20. In an embodiment, the electrode contact region BA1 is arranged along a direction surrounding the display region AA.

In some embodiments, the display panel further includes dummy sub-pixels xsp. At least a part of the dummy sub-pixels xsp is located in the non-display region BA. The dummy sub-pixel xsp includes a first dummy sub-pixel 1xsp. The first dummy sub-pixel 1xsp and the regular sub-pixel sp are both located at a same side of the substrate 10. At least a part of the first dummy sub-pixel 1xsp overlaps with the electrode contact region BA1 in a direction e perpendicular to the substrate 10. The first-color sub-pixel sp1 includes a first light-emitting material layer. That is, the light-emitting layer 12 of the first-color sub-pixel sp1 includes a first light-emitting material layer. The material of the first dummy sub-pixel 1xsp is the same as the first light-emitting material layer. In an embodiment of the present disclosure, the first dummy sub-pixel 1xsp and the first light-emitting material layer are made by using a same mask during a same evaporation process.

In some embodiments, the display panel includes a pixel definition layer 32. The pixel definition layer 32 is configured to space from the adjacent regular sub-pixels sp. The pixel definition layer 32 has an opening in which the light-emitting layer 12 of the sub-pixel is located.

FIG. 2 further shows a driving layer 30 on the substrate 10, where the driving layer 30 includes multiple pixel circuits configured to drive the regular sub-pixels sp to emit light. The pixel circuit includes a thin film transistor 31. In some embodiments, the display panel further includes an encapsulation structure 40 configured to encapsulate the sub-pixels to isolate from water and oxygen to ensure the service life of the sub-pixels.

The display panel provided by embodiments of the present disclosure is provided with first dummy sub-pixels, and the material of the first dummy sub-pixel is the same as the material of the first light-emitting material layer of the first-color sub-pixel in the display region. The first dummy sub-pixels and the first light-emitting material layer are made by using the same mask in the same evaporation process. At least a part of the first dummy sub-pixels overlaps with the electrode contact region, which is equivalent to externally expanding the evaporation edge to the periphery of the display region in the evaporation process. The finally evaporated light-emitting material layer with a larger shadow region is located at the periphery of the display region due to poor bonding between the mask and the substrate to be evaporated caused by the abrupt change at the edge of pattern of a mask. The yield of the organic layer evaporated near the edge of the display region is improved, and the pixel color matching display may not lack of the light-emitting color of the first-color sub-pixels, thereby reducing the display unevenness caused by the display color cast due to poor bonding of the mask, and improving the display quality of products and the yield of production lines.

In some embodiments, at least a part of the edge of the display region AA of the display panel provided by the present disclosure has an arc shape.

In some embodiments, the display region AA has an approximately circular or elliptical shape.

In some embodiments, the first-color sub-pixel sp1 is a red sub-pixel, and the light-emitting material layers of the first dummy sub-pixel 1xsp and the red sub-pixel are manufactured in a same evaporation process, which can improve the yield of the red light-emitting material layer evaporated near the edge of the display region.

In some embodiments, the first-color sub-pixel sp1 is a green sub-pixel, and the light-emitting material layers of the first dummy sub-pixel 1xsp and the green sub-pixel are manufactured in a same evaporation process, which can improve the yield of the green light-emitting material layer evaporated near the edge of the display region.

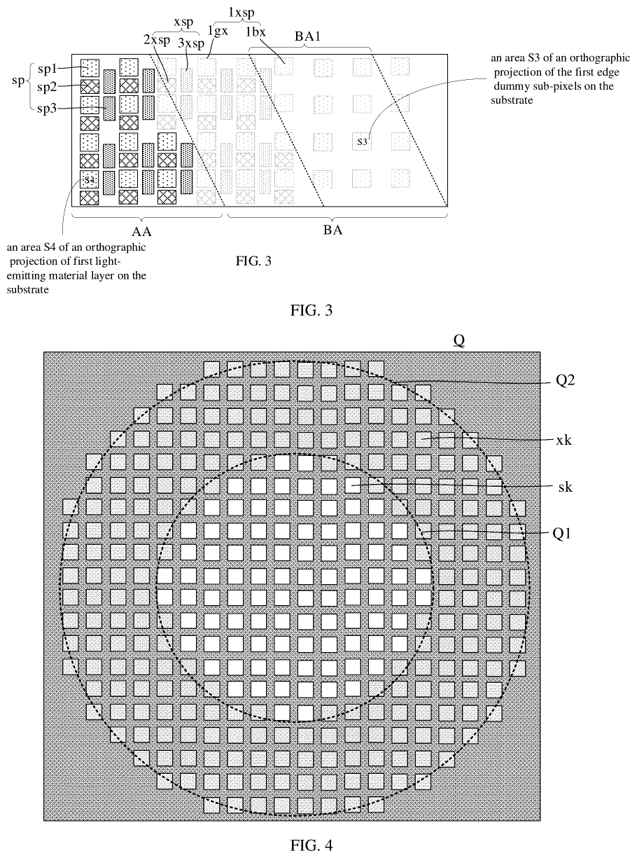

FIG. 3 is a partial schematic diagram of a display panel according to another embodiment of the present disclosure. According to the exemplary embodiment shown in FIG. 3, the first dummy sub-pixel 1xsp further includes a first transition dummy sub-pixel 1gx and a first edge dummy sub-pixel. The first transition dummy sub-pixel 1gx is located at a side of the first edge dummy sub-pixel 1bx close to the display region AA. The first edge dummy sub-pixel 1bx overlaps with the electrode contact region BA1. An orthographic projection of the first transition dummy sub-pixel 1gx on the substrate 10 has the same shape as an orthographic projection of the first light-emitting material layer on the substrate 10. In some embodiments, the first transition dummy sub-pixel 1gx is located between the first edge dummy sub-pixel 1bx and the regular sub-pixel sp, that is, the first transition dummy sub-pixel 1gx is located near the edge of the display region AA. The first transition dummy sub-pixel 1gx and the first light-emitting material layer are manufactured by using the same mask in the same evaporation process.

In some embodiments, the mask is provided with pixel openings and dummy openings. The dummy openings are full-etched opening penetrating through the mask. The pixel opening is configured to evaporate the light-emitting layer of regular sub-pixels sp. At least a part of the dummy openings is configured to evaporate the first transition dummy sub-pixels 1gx. The shape of at least a part of the dummy openings is provided to be the same as the shape of the pixel openings, so that the shape of the orthographic projection of the first transition dummy sub-pixel 1gx on the substrate 10 is the same as the shape of the orthographic projection of the first light-emitting material layer on the substrate 10. For the mask used for evaporating the first light-emitting material layer, the pixel openings for evaporating the first light-emitting material layer have the same shape and size as the dummy openings for evaporating the first transition dummy sub-pixels 1gx, so that the manufacturing accuracy of the pixel openings in the mask can be improved, thereby improving the accuracy of evaporating the light-emitting material layer in the display region.

In some embodiments, a single first transition dummy sub-pixel 1gx has the same area as a single first light-emitting material layer.

The present disclosure further provides a mask, which is applied in an evaporation process to manufacture sub-pixels of a display panel. The mask can be applied to the processes for manufacturing the display panel provided by foregoing embodiments. FIG. 4 is a partial schematic diagram of a mask according to an embodiment of the present disclosure. According to the exemplary embodiment shown in FIG. 4, the mask includes a plurality of sub-regions Q. In an evaporation process, one sub-region Q corresponds to one region to be evaporated in the display panel. FIG. 4 shows an exemplary sub-region Q, which includes a pixel evaporation region Q1 and a dummy evaporation region Q2. The pixel evaporation region Q1 includes a plurality of pixel openings sk. The dummy evaporation region Q2 includes a plurality of dummy openings xk. In a thickness direction of the mask, the dummy opening xk penetrates through the mask. The pixel opening sk is configured to correspond to a regular sub-pixel region in the evaporation process to evaporate the light-emitting material layer of the regular sub-pixel sp. The dummy opening xk is configured to correspond to the dummy sub-pixel region in the evaporation process to evaporate the dummy sub-pixel xsp.

The shapes of the pixel evaporation region Q1 and the dummy evaporation region Q2 in FIG. 4 are only schematic illustrations. FIG. 4 shows an exemplary embodiment in which the edge of the pixel evaporation region Q1 is arc-shaped, which can be applied to manufacture a display panel where at least a part of the edge of the display region is arc-shaped. In addition, the shapes of the pixel opening sk and the dummy opening xk shown in FIG. 4 are only schematic illustrations. In practice, the shapes of the openings in the mask can be designed according to design requirements of the display panel. When the display panel includes the sub-pixels with three colors, the light-emitting material layers of the sub-pixels with three colors are respectively manufactured in different evaporation processes. That is, one type of light-emitting material layer is evaporated in one evaporation process.

For example, the mask shown in FIG. 4 can be used to evaporate the first-color sub-pixel sp1 and the first dummy sub-pixel 1xsp provided by the present disclosure shown in FIG. 1. In the evaporation process, the pixel evaporation region Q1 of the mask corresponds to the display region AA of the display panel to be evaporated, and one pixel opening sk corresponds to one region where the first-color sub-pixel sp1 is located. The dummy evaporation region Q2 corresponds to the non-display region BA of the display panel to be evaporated. At least a part of the dummy openings xk corresponds to the electrode contact region BA1. The evaporation material is deposited through the pixel opening sk in the region where the first-color sub-pixel sp1 is located to form a first light-emitting material layer. The evaporation material is deposited through the dummy opening xk in the electrode contact region BA1 to form the first dummy sub-pixel xsp.

In the mask provided by the present disclosure, the edge having pattern abrupt change is located at a side of the dummy evaporation region Q2 away from the pixel evaporation region Q1. In the process for evaporating sub-pixels of the display panel, the mask is used to evaporate, and the evaporation edge in the evaporation process can be externally expanded to the periphery of the display region, so that the final evaporated light-emitting material layer with a larger shadow region is located at the periphery of the display region due to poor bonding between the mask and the substrate to be evaporated caused by the abrupt change at the edge of pattern of a mask. The yield of the organic layer evaporated near the edge of the display region is improved, and the pixel color matching display may not lack of the light-emitting color of the first-color sub-pixels, thereby reducing the display unevenness caused by the display color cast due to poor bonding of the mask, and improving the display quality of products and the yield of production lines.

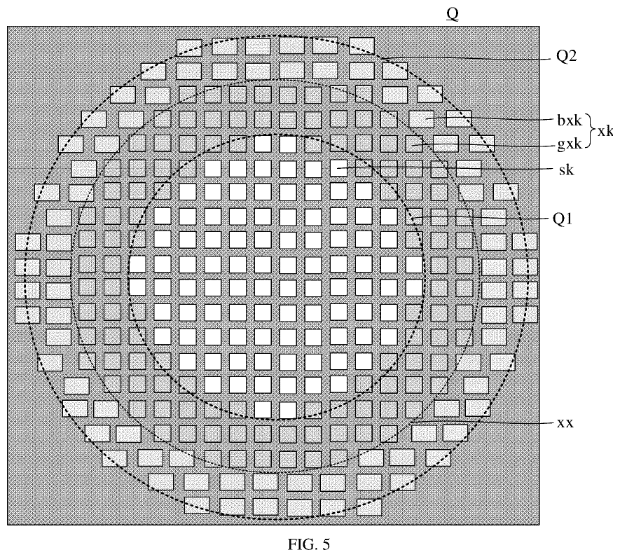

FIG. 5 is a partial schematic diagram of a mask according to another embodiment of the present disclosure. In some embodiments, as shown in FIG. 5, a dummy opening xk includes an edge dummy opening bxk and a transition dummy opening gsk. The transition dummy opening gsk is located at a side of the edge dummy opening bxk close to a pixel evaporation region Q1. A curve xx is shown in a dummy evaporation region Q2, and the dummy openings xk in a region circled by the curve xx are the transition dummy openings gsk. At least a part of the edge dummy openings bxk is configured to correspond to the dummy sub-pixel region in the evaporation process to evaporate the dummy sub-pixels xsp overlapping with the electrode contact region BA1. The area of the edge dummy opening bxk is S₅, and the area of the pixel opening sk is S₆. In some embodiments, S₅ is greater than S₆. In some embodiments, S₅ is less than S₆. In some embodiments,

$$\frac{\vert {S}_{5} - {S}_{6} \vert}{{S}_{6}} \leq 1.$$

In embodiments of the present disclosure, the maximum value of S₅ is twice the value of S₆, and the minimum value of S₅ is one-half of S₆, so that the difference between the size of the edge dummy opening bxk and the size of the pixel opening sk may not be too large, and the pattern abrupt change degree between the pixel evaporation region Q1 and the dummy evaporation region Q2 can be reduced. Doing so may improve the poor bonding caused by the pattern abrupt change of the mask. Additionally, in some embodiments, at least a part of the edge dummy openings bxk is provided for evaporating to form dummy sub-pixels xsp overlapping with the electrode contact region in the evaporation process. The evaporation edge can be externally expanded to the periphery of the display region, so that the final evaporated light-emitting material layer with a larger shadow region is located at the periphery of the display region due to poor bonding between the mask and the substrate to be evaporated caused by the abrupt change at the edge of pattern of a mask. The yield of the organic layer evaporated near the edge of the display region is improved, thereby reducing display unevenness caused by the display color cast due to poor bonding of the mask.

In some embodiments, as shown in FIG. 5, in the evaporation process, the transition dummy openings gsk correspond to the non-display region between the display region AA and the electrode contact region BA1. The transition dummy openings gsk are configured to evaporate the dummy sub-pixels xsp between the display region AA and the electrode contact region BA1. In some embodiments, the dummy sub-pixels xsp located between the display region AA and the electrode contact region BA1 are transition dummy sub-pixels (the first transition dummy sub-pixel 1gx as shown in FIG. 3). The arrangement of the transition dummy openings gsk can improve the manufacturing accuracy of the pixel openings sk in the mask, thereby improving the evaporation accuracy of the organic light-emitting layer of the display region in the evaporation process, and improving the yield of products.

In some embodiments, the transition dummy opening gsk has the same shape as the pixel opening sk.

In some embodiments, the transition dummy opening gsk has the same area as the pixel opening sk.

In some embodiments, in a unit area, the transition dummy openings gsk has the same density as the pixel openings sk.

In some embodiments, the edge dummy opening bxk has substantially the same shape as the pixel opening sk.

In some embodiments, the edge dummy opening bxk has substantially the same area as the pixel opening sk.

In some embodiments, in a unit area, the edge dummy openings bxk have substantially the same total area as the pixel openings sk.

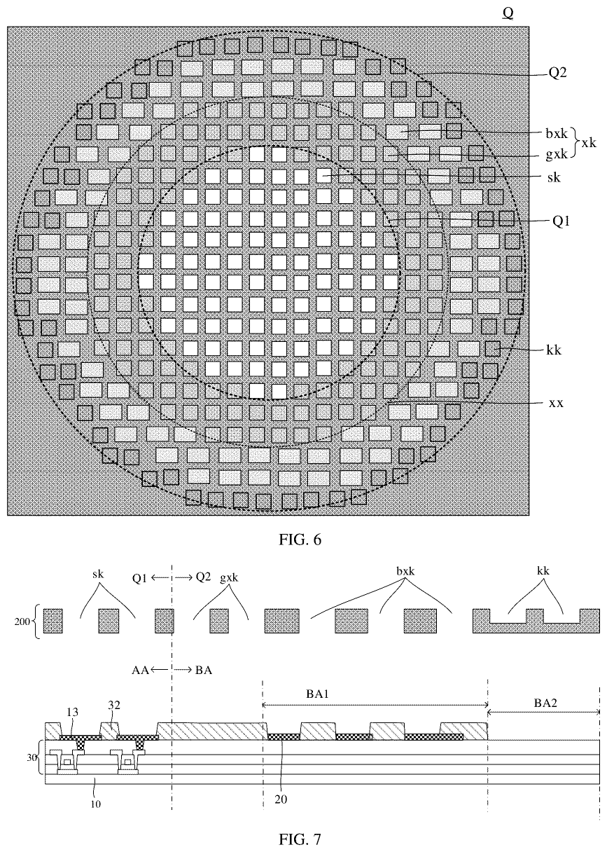

FIG. 6 is a partial schematic diagram of a mask according to another embodiment of the present disclosure. In some embodiments, as shown in FIG. 6, the dummy evaporation region Q2 further includes half-etched openings kk located at a side of the dummy openings xk away from the pixel openings sk. The half-etched opening kk has a depth smaller than the thickness of the mask. In other words, the half-etched openings kk do not penetrate through the mask in the thickness direction of the mask. In the evaporation process, the evaporated material may not be deposited on the display panel to be evaporated through the half-etched openings kk. The half-etched openings kk are arranged at a side of the dummy openings xk away from the pixel openings sk. The half-etched openings kk can form a good transition between the opening region of the mask (that is, a region where the pixel openings and the dummy openings are arranged) and the non-opening region. In the evaporation process, when the mask is stretched to align with the substrate to be evaporated, the half-etched openings kk can absorb stress deformation, so that the tensile strain of the mask is reduced, thereby further improving the evaporation yield.

In some embodiments, the pattern shape of the half-etched openings kk is the same as the pattern shape of the dummy openings xk adjacent to the half-etched openings kk. Further, the density of the half-etched openings kk is the same as the density of the dummy openings xk adjacent to the half-etched openings kk.

In some embodiments, the display panel further includes an encapsulation region located at a side of the electrode contact region BA1 away from the display region AA. When the mask is aligned with the substrate to be evaporated in the evaporation process, the half-etched openings kk correspond to the preset encapsulation region in the evaporation substrate. When the mask is stretched to align with the substrate to be evaporated, the half-etched openings kk can absorb the stress deformation, so that the tensile strain of the mask is reduced, thereby further improving the evaporation yield. In addition, the arrangement of the half-etched openings kk can further externally expand the region poorly aligned when the mask is aligned with the substrate to be evaporated, so that the problem of a larger shadow region of the light-emitting material layer evaporated caused by the abrupt change of the edge of the pattern of the mask can be further improved, thereby further improving the yield of the evaporation process.

FIG. 7 is a schematic diagram showing alignment of the mask with the substrate to be evaporated according to an embodiment of the present disclosure. In some embodiments, as shown in FIG. 7, in the evaporation process, the mask 200 is aligned with the substrate to be evaporated. The pixel evaporation region Q1 corresponds to the display region AA, and the dummy evaporation region Q2 corresponds to the non-display region BA. The pixel openings sk of the pixel evaporation region Q1 correspond to the openings of the pixel definition layer 32 to evaporate the light-emitting material layer in the openings of the pixel definition layer 32. The edge dummy openings bxk correspond to the electrode contact region BA1, so that a light-emitting material is evaporated and deposited in the electrode contact region BA1 to form the dummy sub-pixels xsp. In some embodiments, the display panel further includes an encapsulation region BA2. The encapsulation region BA2 is located at a side of the electrode contact region BA1 away from the display region AA. The half-etched openings kk correspond to the encapsulation region BA2. The mask 200 shown in FIG. 7 further includes transition dummy openings gxk. The transition dummy openings gxk correspond to the non-display region between the electrode contact region BA1 and the display region AA.

In some embodiments, within the same region, the density of the first transition dummy sub-pixels 1gx is the same as the density of the first light-emitting material layer. In the mask used for evaporation of the first light-emitting material layer, transition dummy openings gxk are provided between the pixel openings kk and the edge dummy openings bxk, and the arrangement densities of the transition dummy openings gxk and the pixel openings kk are the same. The arrangement of the transition dummy openings gxk can improve the manufacturing accuracy of the pixel openings kk in the mask, thereby improving the accuracy of the evaporated first light-emitting material layer in the display region.

In some embodiments, as shown in FIG. 3, the dummy sub-pixel further includes a second dummy sub-pixel 2xsp and a third dummy sub-pixel 3xsp that are close to the edge of the display region AA. The second-color sub-pixel sp2 includes a second light-emitting material layer, and the third-color sub-pixel sp3 includes a third light-emitting material layer. The second dummy sub-pixel 2xsp is made of same material as the second light-emitting material layer. The second dummy sub-pixel 2xsp and the second light-emitting material layer are manufactured by using the same mask in the same evaporation process. The third dummy sub-pixel 3xsp is made of same material as the third light-emitting material layer. The third dummy sub-pixel 3xsp and the third light-emitting material layer are manufactured by the same mask in the same evaporation process. The second dummy sub-pixels 2xsp arranged close to the edge of the display region AA have the same shape and density as the second light-emitting material layer in the display region AA, so that the manufacturing accuracy of the pixel openings of the mask used for evaporation of the second light-emitting material layer is increased, thereby improving the precision of evaporation of the second light-emitting material layer in the display region. The third dummy sub-pixels 3xsp arranged close to the edge of the display region AA have the same shape and density as the third light-emitting material layer in the display region AA, so that the manufacturing accuracy of the pixel openings of the mask used for evaporation of the third light-emitting material layer is increased, thereby improving the precision of evaporation of the third light-emitting material layer in the display region. As a result, the yield of products is improved.

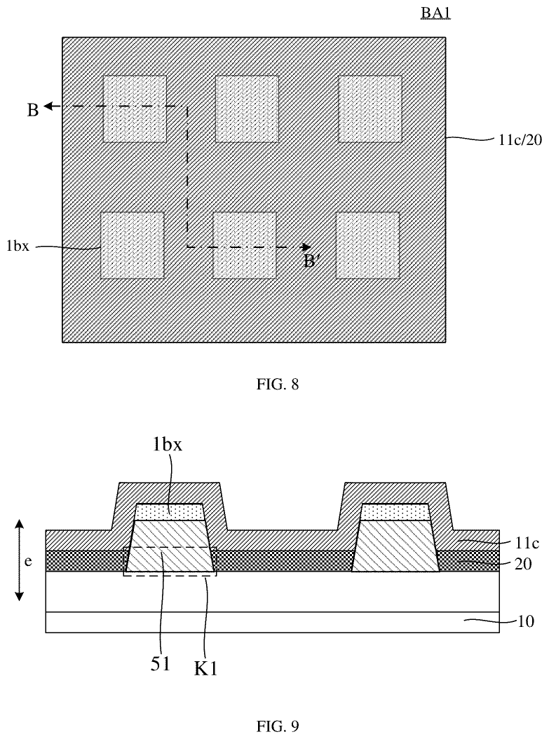

FIG. 8 is a partial schematic diagram of an electrode contact region of a display panel according to another embodiment of the present disclosure, and FIG. 9 is a cross-sectional view at a line B-B′ in FIG. 8 according to an embodiment of the present disclosure. In some embodiments, as shown in FIG. 8 and FIG. 9, in the electrode contact region BA1, the electrode layer 11c covers at least a part of the first edge dummy sub-pixels 1bx, and is in contact with a contact metal layer 20 in at least a part of the region outside the first edge dummy sub-pixels 1bx. In embodiments of the present disclosure, the first edge dummy sub-pixels 1bx overlap with the electrode contact region BA1, and the first edge dummy sub-pixels 1bx and the first light-emitting material layer are manufactured in the same evaporation process. The arrangement of the first edge dummy sub-pixels can externally expand the evaporation edge in the evaporation process to the periphery of the display region, so that the final evaporated light-emitting material layer with a larger shadow region is located at the periphery of the display region due to poor bonding between the mask and the substrate to be evaporated caused by the abrupt change at the edge of pattern of a mask. The yield of the first light-emitting material layer evaporated near the edge of the display region is improved, thereby reducing the display unevenness caused by the display color cast due to poor bonding of the mask. Since the first edge dummy sub-pixels 1bx and the first light-emitting material layer are manufactured in the same evaporation process, the process for manufacturing the first edge dummy sub-pixel 1bx is before the process for manufacturing the electrode layer 11c. The electrode layer 11c extends from the display region AA to the electrode contact region BA1, and is in contact with the contact metal layer 20 in at least a part of the region outside the first edge dummy sub-pixels 1bx, thereby achieving the connection performance between the electrode layer 11c and the contact metal layer 20.

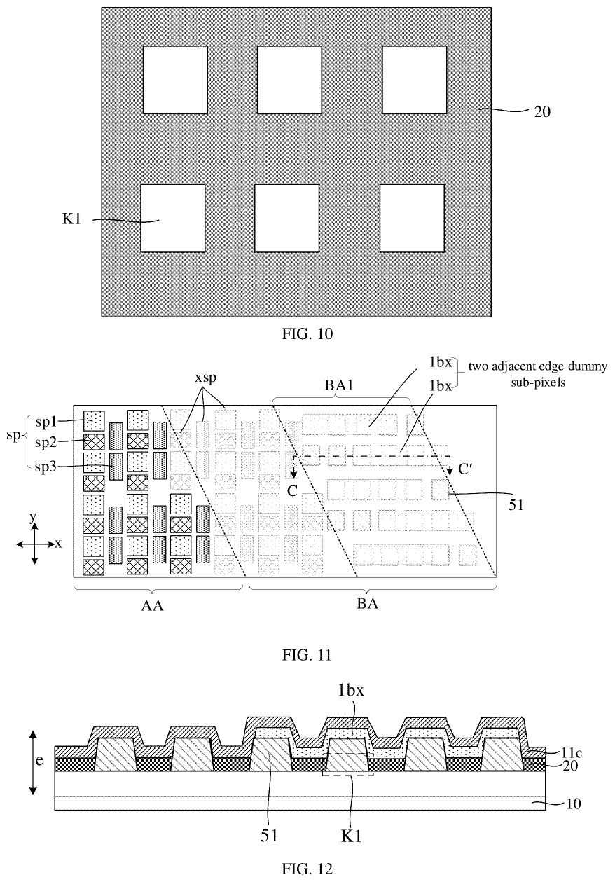

FIG. 10 is a partial schematic diagram of a contact metal layer of a display panel according to another embodiment of the present disclosure. In some embodiments, as shown in FIG. 10, the contact metal layer 20 in the electrode contact region BA1 has a plurality of first openings K1. The first opening K1 passes through the contact metal layer 20 in the thickness direction of the contact metal layer 20. Referring to FIG. 9 and FIG. 10 together, the electrode contact region BA1 further includes a plurality of insulating portions 51 at least partially located in the first opening K1. The first edge dummy sub-pixel 1bx overlaps with the insulating portion 51 in a direction e perpendicular to the substrate 10. In this embodiment, the electrode layer 11c is in contact with the contact metal layer 20 in a region outside the plurality of first openings K1, so that the contact resistance between the contact metal layer 20 and the electrode layer 11c can be reduced, and the voltage drop of signal transmission to the electrode layer 11c is reduced, thereby reducing the power consumption of the display panel.

In some embodiments, the direction e perpendicular to the substrate 10 is schematically shown in FIG. 9. It can be seen from FIG. 9 that an orthographic projection of the first edge dummy sub-pixel 1bx on the substrate 10 is located within an orthographic projection of the insulating portion 51 on the substrate 10. In such embodiments, by arranging the first edge dummy sub-pixels 1bx to overlap with the electrode contact region BA1, the evaporation edge in the evaporation process can be externally expanded to the periphery of the display region. As such, the final evaporated light-emitting material layer with a larger shadow region is located at the periphery of the display region due to poor bonding between the mask and the substrate to be evaporated caused by the abrupt change at the edge of pattern of a mask. The yield of the first light-emitting material layer evaporated near the edge of the display region is improved, thereby reducing the display unevenness caused by the display color cast due to poor bonding of the mask. In addition, the arrangement of the first edge dummy sub-pixel 1bx may not affect the contact area between the electrode layer 11c and the contact metal layer 20, achieving the suitable contact performance between the electrode layer 11c and the contact metal layer 20.

In some embodiments, in the direction perpendicular to the substrate 10, the first edge dummy sub-pixels 1bx overlap with m insulating portions 51, where m is a positive integer, and m≥2. FIG. 11 is a partial schematic diagram of an electrode contact region of a display panel according to another embodiment of the present disclosure, and FIG. 12 is a cross-sectional view at a line C-C′ in FIG. 11 according to another embodiment of the present disclosure. Referring FIG. 11 and FIG. 12, in the direction e perpendicular to the substrate 10, the first edge dummy sub-pixel 1bx overlaps with four insulating portions 51. In some embodiments, the contact metal layer 20 has a plurality of first openings K1. At least a part of the insulating portion 51 is located in the first opening K1, and the electrode layer 11c is electrical connected to and in contact with the contact metal layer 20 in a region outside the insulating portion 51, which can reduce the contact resistance between the electrode layer 11c and the contact metal layer 20. Because the first edge dummy sub-pixel 1bx is manufactured before the electrode layer 11c, the first edge dummy sub-pixel 1bx may have certain influence on the contact between the electrode layer 11c and the contact metal layer 20. The first edge dummy sub-pixel 1bx is arranged to overlap with at least two insulating portions 51, so that the shape and size of the first edge dummy sub-pixel 1bx can be adapted to design the overlapping manner between the first edge dummy sub-pixel 1bx and the insulating portion 51, thereby achieving the overlapping area between the first edge dummy sub-pixel 1bx and a position other than the position of the first opening of the contact metal layer 20 to be as small as possible. Therefore, the arrangement of the first edge dummy sub-pixel 1bx is prevented from affecting the contact area between the electrode layer 11c and the contact metal layer 20.

In some embodiments, the shape and size of the first edge dummy sub-pixel 1bx can be adapted to design the size and position of the first opening K1, so that the shape and size of the first edge dummy sub-pixel 1bx are close to the first-color sub-pixels sp1 in the display region AA while the contact area between the electrode layer 11c and the contact metal layer 20 is sufficiently large.

It should be noted that, the size involved in the present disclosure generally refers to an area size. For example, the size of the first edge dummy sub-pixel 1bx refers to an area of the orthographic projection of the first edge dummy sub-pixel 1bx on the substrate 10.

In some embodiments, as shown in FIG. 12, the m insulating portions 51 overlapping with the same first edge dummy sub-pixel 1bx are arranged in a same direction. In this embodiment, multiple factors such as the area of the orthographic projection of the first edge dummy sub-pixel 1bx on the substrate 10, the area of the orthographic projection of the insulating portion 51 on the substrate 10, and the relationship between the size of the first edge dummy sub-pixel 1bx and the size of the first-color sub-pixel to flexibly design the first edge dummy sub-pixel 1bx can be comprehensively considered. The size and arrangement of the insulating portions 51 can also be designed according to the desired size of the first edge dummy sub-pixel 1bx, and the first edge dummy sub-pixels 1bx are arranged to overlap with the m insulating layers 51 arranged in the same direction, so that the size of the edge dummy sub-pixel 1bx is close to the size of the first-color sub-pixel sp1 in the display region AA. In addition, the first edge dummy sub-pixel 1bx overlaps with the electrode contact region BA1 without affecting the electrical contact performance between the electrode layer 11c and the contact metal layer 20.

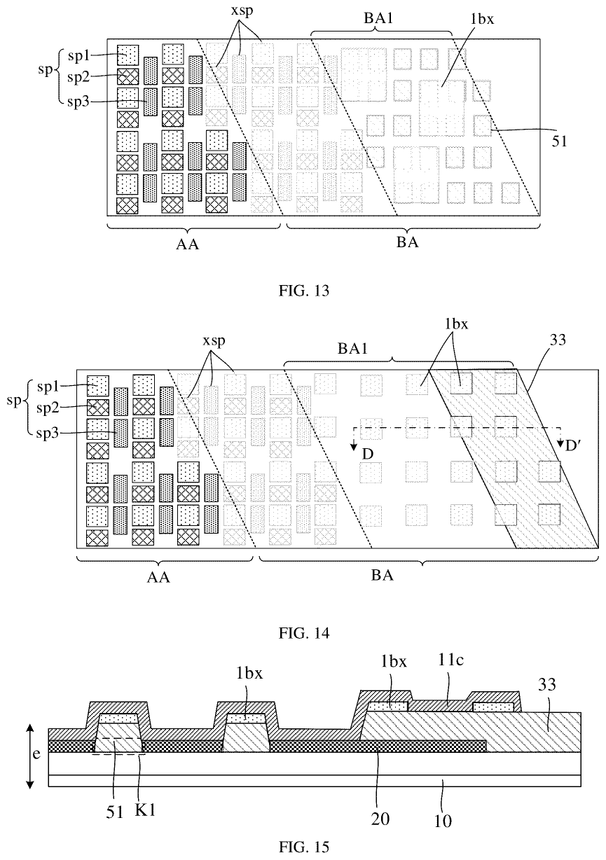

In some embodiments, m≥3, and m insulating portions are arranged in rows and columns. The arrangement in rows and columns means that m insulating portions 51 are arranged in an array in a row direction and in a column direction. For example, when m=3, three insulating portions 51 may be arranged in a triangular array. FIG. 13 is a partial schematic diagram of a display panel according to another embodiment of the present disclosure. Taking m=4 as an example, as shown in FIG. 13, the first edge dummy sub-pixel 1bx overlaps with four insulating portions 51 that are arranged in 2 rows and 2 columns. With such a configuration, when the first edge dummy sub-pixel 1bx overlaps with multiple insulating portions 51, the area of the region other than first opening region covered by the first edge dummy sub-pixel 1bx is relatively small, the arrangement of the first edge dummy sub-pixel 1bx is prevented from affecting the contact area between the electrode layer 11c and the contact metal layer 20.

FIG. 14 is a partial schematic diagram of a display panel according to another embodiment of the present disclosure, and FIG. 15 is a cross-sectional view at a line D-D′ in FIG. 14 according to an embodiment of the present disclosure. In some embodiments, referring to FIG. 14 and FIG. 15, the electrode contact region BA1 further includes an insulation protection portion 33 located at a side away from the display region AA. The insulation protection portion 33 covers the edge of the contact metal layer 20 at a side away from the display region AA. In the direction e perpendicular to the substrate 10, at least a part of the first edge dummy sub-pixels 1bx overlaps with the insulating protection portion 33. In this embodiment, the insulating protection portion 33 can protect the contact metal layer 20 at a side away from the display region AA, to prevent the contact metal layer 20 from being exposed and corroded to influence electrical performance. At least a part of the first edge dummy sub-pixels 1bx is arranged to overlap with the insulating protection portion 33, so that the evaporation edge in the evaporation process can be externally expanded to the periphery of the display region, and the final evaporated light-emitting material layer with a larger shadow region is located at the electrode contact region of the periphery of the display region due to poor bonding between the mask and the substrate to be evaporated caused by the abrupt change at the edge of pattern of a mask. The yield of the first light-emitting material layer evaporated near the edge of the display region is improved, thereby reducing the display unevenness caused by the display color cast due to poor bonding of the mask, and improving the display quality of products and the yield of production lines.

In some embodiments, the insulating protection portion 33 and the pixel definition layer in the display region AA are manufactured in the same process.

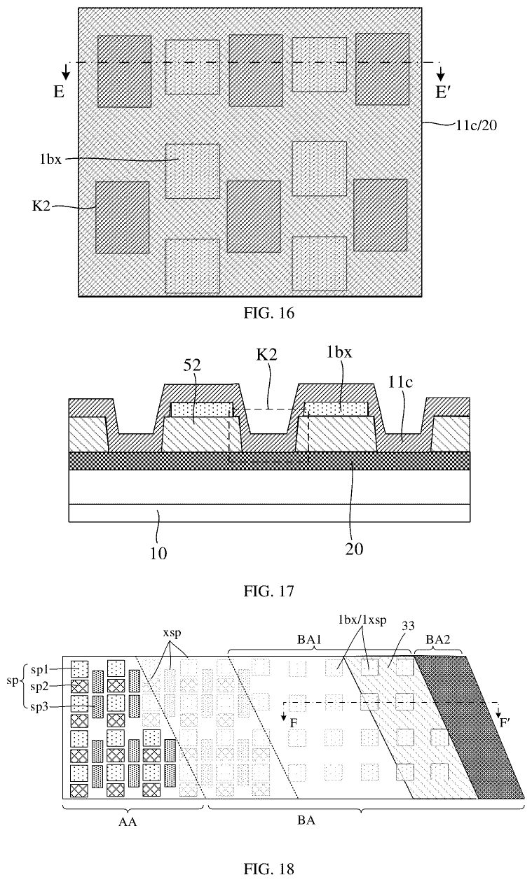

FIG. 16 is a partial schematic diagram of an electrode contact region in a display panel according to another embodiment of the present disclosure, and FIG. 17 is a cross-sectional view at a line E-E′ in FIG. 16 according to an embodiment of the present disclosure. In some embodiments, as shown in FIG. 16 and FIG. 17, the electrode contact region BA1 further includes an insulating layer 52 located between the contact metal layer 20 and the electrode layer 11c. The insulating layer 52 has a plurality of second openings K2. The electrode layer 11c passes through the second openings K2 to contact with the contact metal layer 20. An overlapping area between the first edge dummy sub-pixel 1bx and the second opening K2 is S₁, and an area of the second opening K2 is S₂, where

$${S}_{1} \leq \frac{{S}_{2}}{3} .$$

In this embodiment, in the electrode contact region BA1, the electrode layer 11c is in contact with the contact metal layer 20 through the second opening K2, so that the contact resistance between the contact metal layer 20 and the electrode layer 11c can be reduced. Furthermore, the voltage drop of signal transmission to the electrode layer 11c is reduced, thereby reducing the power consumption of the display panel. In addition, the overlapping area between the first edge dummy sub-pixel 1bx and the second opening K2 is no more than one third of the area of the second opening K2. The design of the first edge dummy sub-pixel 1bx can externally expand the evaporation edge in the evaporation process to the electrode contact region BA1, so that the final evaporated light-emitting material layer with a larger shadow region is located at the electrode contact region of the periphery of the display region due to poor bonding between the mask and the substrate to be evaporated caused by the abrupt change at the edge of pattern of a mask. The yield of the first light-emitting material layer evaporated near the edge of the display region is improved, thereby reducing the display unevenness caused by the display color cast due to poor bonding of the mask, and improving the display quality of products and the yield of production lines. In addition, the overlapping area between the first edge dummy sub-pixel 1bx and the second opening K2 is relative small without affecting the influence on the electrical contact performance between the electrode layer 11c and the contact metal layer 20.

In some embodiments, the electrode layer 11c is in contact with the contact metal layer 20 through the second opening K2, and S₁=0 is set. That is, the first edge dummy sub-pixel 1bx does not overlap with the second opening K2, so that the arrangement of the first edge dummy sub-pixels 1bx does not affect the electrical contact performance between the electrode layer 11c and the contact metal layer 20.

In some embodiments, the position and size of the second opening K2 in the insulating layer 52 can be adjusted according to the position of the first edge dummy sub-pixel 1bx, without affecting the electrical contact performance between the electrode layer 11c and the contact metal layer 20.

In some embodiments, as shown in FIG. 11, a plurality of first-color sub-pixels sp1 in the display region AA is arranged in pixel rows in a first direction x (not labeled in FIG. 11), and there is a misalignment between two first edge dummy sub-pixels 1bx adjacent to each other in a second direction y. The second direction y intersects with the first direction x. In this embodiment, arrangement manner of the first edge dummy sub-pixels 1bx is designed to adapt to the edge shape (for example, an arc-shaped edge) of the display region AA. The arrangement of the first edge dummy sub-pixels 1bx can externally expand the evaporation edge in the evaporation process to the electrode contact region BA1, so that the yield of the first light-emitting material layer evaporated near the edge of the display region is improved, thereby reducing the display unevenness caused by the display color cast due to poor bonding of the mask, and improving the display quality of products and the yield of production lines. The arrangement of the first edge dummy sub-pixels 1bx can be further designed to prevent the arrangement of the first edge dummy sub-pixels 1bx from affecting the electrical contact performance between the electrode layer 11c and the contact metal layer 20.

In some embodiments, an area of the orthographic projection of the first edge dummy sub-pixel 1bx on the substrate 10 is S₃, and an area of the orthographic projection of the first light-emitting material layer on the substrate 10 is S₄, where

$$\frac{\vert {S}_{3} - {S}_{4} \vert}{{S}_{3}} \leq 1.$$

That is, the maximum value of S₃ is twice the value of S₄, and the minimum value of S₃ is at least one-half the value of S₄, so that the difference between the size of the first edge dummy sub-pixel 1bx and the size of the first-color sub-pixel sp1 may not be too large, and the pattern abrupt change degree of the mask used in the evaporation process can be reduced, thereby improving the poor bonding caused by the pattern abrupt change of the mask.

In some embodiments, S₃ is greater than S₄, that is, the size of the first edge dummy sub-pixel 1bx is greater than the size of the first light-emitting material layer. This embodiment can be combined with the embodiment of FIG. 7 described above, and the orthographic projection of the first edge dummy sub-pixel 1bx on the substrate 10 is located in the orthographic projection of the insulating portion 51 on the substrate 10. This embodiment can also be combined with the FIG. 11 or FIG. 12 described above, and the size of the insulating portion 51 is designed by adapting the size of the first edge dummy sub-pixel 1bx, so that the first edge dummy sub-pixels 1bx overlap with two or more insulating portions 51.

In other embodiments, S₃ is smaller than S₄. That is, the size of the first edge dummy sub-pixel 1bx is smaller than the size of the first light-emitting material layer. This embodiment can be combined with the embodiments of FIG. 8, FIG. 11 or FIG. 12 described above, and the size of the insulating portion 51 is designed by adapting the size of the first edge dummy sub-pixel 1bx.

In some embodiments, S₃=S₄, that is, the size of the first dummy edge sub-pixel 1bx is close to the size of the first-color sub-pixel sp1. In some embodiments, the arrangement density of the first dummy sub-pixels is substantially the same as the arrangement density of the first-color sub-pixels sp1 in the display region. In the mask used in the evaporation process, in an embodiment, the size of the edge dummy openings bxk is substantially the same as the pixel openings sk. With such a configuration, the pattern abrupt change between the pixel evaporation region Q1 and the dummy evaporation region Q2 in the mask is improved. That is, the abrupt change of bonding caused by the inconsistency of the pattern density of the plate, the bonding tightly between the mask and the substrate to be evaporated is improved while simplifying the process for manufacturing the mask to ensure the yield of the first light-emitting material layer evaporated near the edge of the display region. Therefore, the display unevenness caused by the display color cast due to poor bonding of the mask can be improved, and the display quality of products and the yield of production lines are improved.

FIG. 18 is a partial schematic diagram of a display panel according to another embodiment of the present disclosure, and FIG. 19 is a cross-sectional view at a line F-F′ in FIG. 18 according to an embodiment of the present disclosure. In some embodiments, as shown in FIG. 18, a non-display region BA further includes an encapsulation region BA2 located at the side of the electrode contact region BA1 away from the display region. In a direction e perpendicular to the substrate 10, the first dummy sub-pixels 1xsp do not overlap with the encapsulation region BA2.

As shown in FIG. 19, the encapsulation structure 40 includes an encapsulation cover plate 60. The encapsulation cover plate 60 covers the display region AA and extends to the non-display region BA. An encapsulation metal 61 is provided in the encapsulation region BA2. In the encapsulation region BA2, the encapsulation cover plate 60 is connected to the encapsulation metal 61 through a frame-sealing glue 62. In this embodiment, the first dummy sub-pixels 1xsp do not overlap with the encapsulation region BA2, so that the first dummy sub-pixel 1xsp is prevented from covering the encapsulation metal 61 and the encapsulation reliability is not affected.

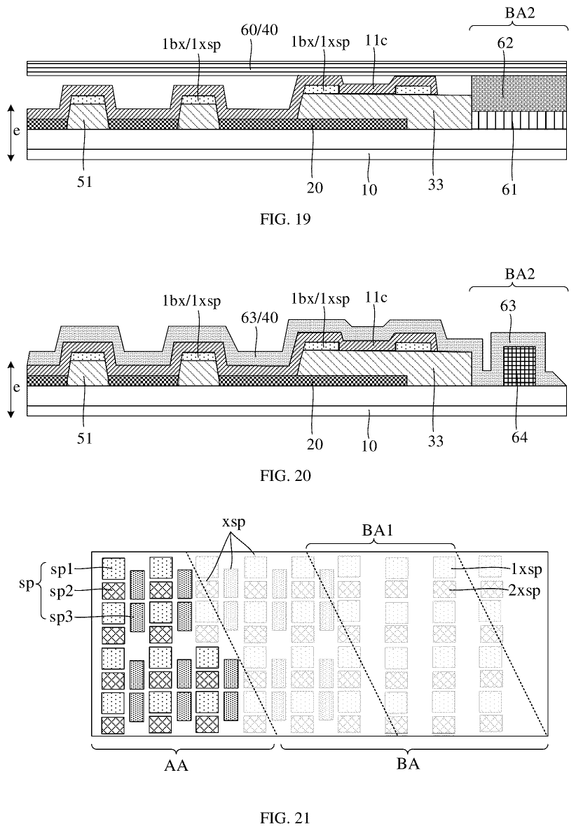

FIG. 20 is a cross-sectional view at a line F-F′ in FIG. 18 according to another embodiment of the present disclosure. In some embodiments, as shown in FIG. 20, the encapsulation structure 40 includes an inorganic encapsulation layer 63. A retaining wall 64 is provided in the encapsulation region BA2. The inorganic encapsulation layer 63 covers the display region AA. The inorganic encapsulation layer 63 extends from the display region AA to the non-display region BA, and extends to a side of the retaining wall 64 away from the display region AA. In this embodiment, the encapsulation region BA2 can also be understood as an encapsulation border in the non-display region. The first dummy sub-pixels 1xsp do not to overlap with the encapsulation region BA2, so that the first dummy sub-pixel 1xsp can be prevented from being exposed to form a water and oxygen intruding path, thereby achieving encapsulation reliability.

In some embodiments, the dummy sub-pixel further includes a second dummy sub-pixel. FIG. 21 is a top view of a display panel according to another embodiment of the present disclosure. According to the embodiment shown in FIG. 21, the display panel further includes second dummy sub-pixels 2xsp located at the same side of the substrate 10 as the regular sub-pixels sp. In a direction perpendicular to the substrate 10, at least a part of the second dummy sub-pixels 2xsp overlaps with the electrode contact region BA1. The second-color sub-pixel sp2 includes a second light-emitting material layer. The material of the second dummy sub-pixel 2xsp is the same as the material of the second light-emitting material layer. In this embodiment, the first dummy sub-pixels 1xsp and the second dummy sub-pixels 2xsp are arranged simultaneously. The arrangement of the first dummy sub-pixel 1xsp can externally expand the evaporation edge of evaporating the first light-emitting material layer to the electrode contact region BA1, so that the final evaporated light-emitting material layer with a larger shadow region is located at the electrode contact region of the periphery of the display region due to poor bonding between the mask and the substrate to be evaporated caused by the abrupt change at the edge of pattern of a mask. The yield of the first light-emitting material layer evaporated near the edge of the display region is improved, and the light-emitting color of the first-color sub-pixels may not lack when the pixel color matching display is performed near the edge of the display region. In addition, the arrangement of the second dummy sub-pixel 2xsp can externally expand the evaporation edge of evaporating the second light-emitting material layer to the electrode contact region BA1, so that the final evaporated light-emitting material layer with a larger shadow region is located at the electrode contact region of the periphery of the display region due to poor bonding between the mask and the substrate to be evaporated caused by the abrupt change at the edge of pattern of a mask. The yield of the second light-emitting material layer evaporated near the edge of the display region is improved, and the light-emitting color of the second-color sub-pixels may not lack when the pixel color matching display is performed near the edge of the display region. This embodiment can ensure the yield of the first light-emitting material layer and the second light-emitting material layer evaporated near the edge of the display region, improve the display color cast due to poor bonding of the mask, and can further improve the color mixing problem due to the poor bonding between the mask and the substrate to be evaporated in the processes for evaporating the first light-emitting material layer and the second light-emitting material layer, thereby improving display quality of products and yield of production lines.

The second dummy sub-pixels 2xsp overlapping with the electrode contact region BA1 are the second edge dummy sub-pixels. In some embodiments, the second edge dummy sub-pixel has the same shape as the second-color sub-pixel sp2. In some embodiments, an area of the orthographic projection of the second edge dummy sub-pixel on the substrate is S₇, and an area of the orthographic projection of the second light-emitting material layer on the substrate is S₈, where

$$\frac{\vert {S}_{7} - {S}_{8} \vert}{{S}_{8}} \leq 1.$$

In some embodiments, the contact metal layer 20 in the electrode contact region BA1 has first openings K1, at least a part of the insulating portion 51 is located in the first opening K1. The electrode layer 11c is in contact with the contact metal layer 20 in a region other than the first opening region. The second dummy sub-pixel 2xsp overlaps with the insulating portion 51.

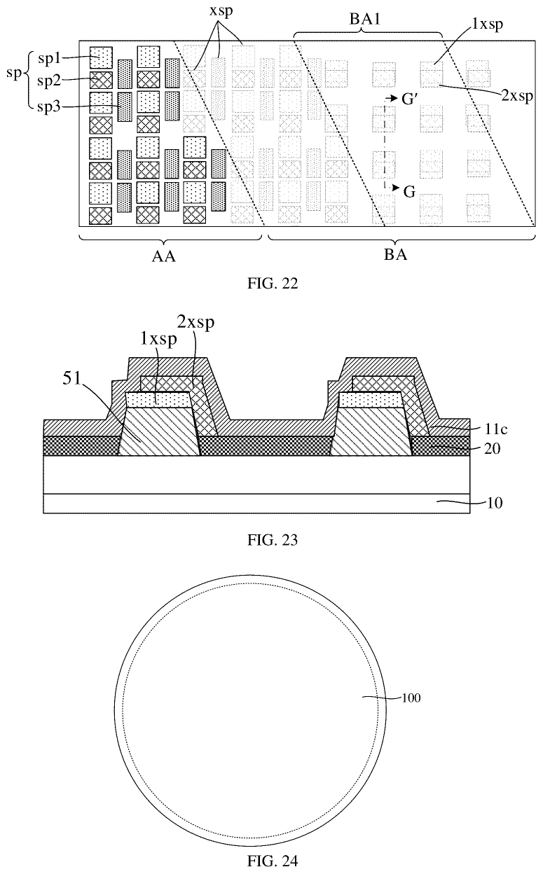

FIG. 22 is a top view of a display panel according to another embodiment of the present disclosure, and FIG. 23 is a cross-sectional view at a line G-G′ in FIG. 22 according to an embodiment of the present disclosure. In some embodiments, referring to FIG. 22 and FIG. 23, in the electrode contact region BA1, the first dummy sub-pixel 1xsp at least partially overlaps with the second dummy sub-pixel 2xsp. In FIG. 23, the first dummy sub-pixel 1xsp is located at a side of the second dummy sub-pixel 2xsp close to the substrate 10, that is, the process for manufacturing the first dummy sub-pixel 1xsp is before the process for manufacturing the second dummy sub-pixel 2xsp. In another embodiment, the second dummy sub-pixel 2xsp is located at a side of the first dummy sub-pixel 1xsp close to the substrate 10, which is not shown in the drawings.

In some embodiments, the first dummy sub-pixel 1xsp and the second dummy sub-pixel 2xsp are provided simultaneously, which can ensure the yield of the first light-emitting material layer and the second light-emitting material layer evaporated near the edge of the display region, thereby reducing the display unevenness caused by the display color cast due to poor bonding of the mask, and improving the display quality of products and the yield of production lines. The first dummy sub-pixel 1xsp at least partially overlaps with the second dummy sub-pixel 2xsp, so that the area occupied by the dummy sub-pixels in the electrode contact region BA1 can be reduced to reduce the influence of the dummy sub-pixels on the contact area between the electrode layer 11c and the contact metal layer 20, and ensure the electrical contact performance between the electrode layer 11c and the contact metal layer 20.

In some embodiments, the first-color sub-pixel sp1 is a red sub-pixel, and the second-color sub-pixel sp2 is a green sub-pixel. In other embodiments, the first-color sub-pixel sp1 is a green sub-pixel, and the second-color sub-pixel sp2 is a red sub-pixel. The light-emitting material layer of the blue sub-pixels of the display panel has a relatively small thickness, so that poor bonding caused by the abrupt change of the pattern of the mask at the edge of the display region has relatively little influence on the process of evaporating the blue light-emitting material layer. In embodiments of the present disclosure, at least a part of the dummy sub-pixels corresponding to the red sub-pixels and at least a part of the dummy sub-pixels corresponding to the green sub-pixels are both arranged to overlap with the electrode contact region BA1, so that the evaporation edge in the process for evaporating the red light-emitting material layer is externally expanded to the electrode contact region BA1. The evaporation edge in the process for evaporating the green light-emitting material layer is externally expanded to the electrode contact region BA1, thereby achieving the yield of the red light-emitting material layer and the green light-emitting material layer evaporated at the edge of the display region AA, improving the cyan display at the edge of the display region caused by poor bonding of the mask when the red light-emitting material layer is evaporated, and further improving the pink display at the edge of the display region caused by poor bonding of the mask when the green light-emitting material layer is evaporated. Embodiments of the present disclosure can improve display unevenness caused by the display color cast at the edge of the display region, and improve the display quality of the product and the yield of the production lines. In addition, the designed positions of the two kinds of dummy sub-pixels in the electrode contact region BA1 can ensure that the electrical contact performance between the electrode layer 11c and the contact metal layer 20 is not affected.

The present disclosure further provides a display apparatus. FIG. 24 is a schematic diagram of a display apparatus according to an embodiment of the present disclosure. As shown in FIG. 24, the display apparatus includes a display panel 100 provided by any of embodiments of the present disclosure. The structure of the display panel 100 has been described in the above embodiments, which will not be elaborated here. The shape of the display apparatus in FIG. 24 is only a schematic illustration, which is not limited in the present disclosure. The display apparatus in embodiments of the present disclosure may be any apparatus having a display function, such as a mobile phone, a tablet computer, a laptop computer, an electronic paper book, a television, a smart watch, and the like.

The above are merely some embodiments of the present disclosure, which, as mentioned above, are not intended to limit the present disclosure. Within the principles of the present disclosure, any modification, equivalent substitution, improvement shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various obvious modifications, readjustments, and substitutions without departing from the scope of the present disclosure.

What is claimed is:

1. A display panel defining a display region and a non-display region, wherein the non-display region comprises an electrode contact region arranged along a direction surrounding the display region, and the display panel comprises:
a substrate;
first dummy sub-pixels and regular sub-pixels located at a same side of the substrate, wherein the first dummy sub-pixels comprise first edge dummy sub-pixels overlapping with the electrode contact region in a direction perpendicular to the substrate; the regular sub-pixels are located in the display region and comprise first-color sub-pixels; each of the regular sub-pixels comprises a first electrode, the first electrodes of the regular sub-pixels are connected to each other to form an electrode layer, and the electrode layer extends from the display region to the non-display region, and is in electrical contact with a contact metal layer in the electrode contact region; and
pixel circuits configured to drive the regular sub-pixels to emit light, wherein the pixel circuits do not overlap with the first dummy sub-pixels in the direction perpendicular to the substrate,
wherein the first-color sub-pixels each comprise a first light-emitting material layer, the first dummy sub-pixels comprise a same material as the first light-emitting material layer;
wherein, in a direction parallel to the substrate, the first dummy sub-pixels are discontinuous with the first light-emitting material layer; and
wherein the electrode layer covers at least a part of the first edge dummy sub-pixels in the electrode contact region, and is in contact with the contact metal layer in at least a partial region other than the first edge dummy sub-pixels.

2. The display panel according to claim 1, wherein the electrode contact region further comprises insulating portions; and
wherein the contact metal layer has first openings, the insulating portions are at least partially located in the first openings, and the first edge dummy sub-pixels overlap with at least one of the insulating portions in the direction perpendicular to the substrate.

3. The display panel according to claim 2, wherein an orthographic projection of the first edge dummy sub-pixels on the substrate is located within an orthographic projection of the insulating portions on the substrate.

4. The display panel according to claim 2, wherein the first edge dummy sub-pixels overlap with m insulating portions in the direction perpendicular to the substrate, where m is a positive integer and m≥2.

5. The display panel according to claim 4, wherein the m insulating portions are arranged in a same direction.

6. The display panel according to claim 4, wherein m≥3, and the m insulating portions are arranged in rows and columns.

7. The display panel according to claim 2, wherein the electrode contact region further comprises an insulation protection portion covering an edge at a side of the contact metal layer away from the display region;
wherein at least a part of the first edge dummy sub-pixels overlaps with the insulation protection portion in the direction perpendicular to the substrate.

8. The display panel according to claim 1, wherein the electrode contact region further comprises an insulating layer located between the contact metal layer and the electrode layer;
wherein the insulating layer has second openings, and the electrode layer is in contact with the contact metal layer through the second openings; and
wherein each of the first dummy sub-pixels does not overlap with any of the second openings.

9. The display panel according to claim 1, wherein in the display region, the first-color sub-pixels are arranged in pixel rows in a first direction, and two adjacent first edge dummy sub-pixels are misaligned in a second direction, and the second direction intersects with the first direction.

10. The display panel according to claim 1, wherein an area S₃ of an orthographic projection of a single first edge dummy sub-pixel on the substrate and an area S₄ of an orthographic projection of a single first light-emitting material layer on the substrate satisfy
$$\frac{\vert {S}_{3} - {S}_{4} \vert}{{S}_{3}} \leq 1.$$

11. The display panel according to claim 10, wherein S₃=S₄.

12. The display panel according to claim 1,
wherein the first dummy sub-pixels further comprise first transition dummy sub-pixels located at a side of the first edge dummy sub-pixels adjacent to the display region; and
wherein an orthographic projection of each of the first transition dummy sub-pixels on the substrate has a same shape as an orthographic projection of the first light-emitting material layer on the substrate.

13. The display panel according to claim 12, wherein a single first transition dummy sub-pixel has the same shape as a single first light-emitting material layer, and a single first transition dummy sub-pixel has the same area as a single first light-emitting material layer, in a same unit area, an arrangement of the first transition dummy sub-pixels is the same as an arrangement of first light-emitting material layers of the first-color sub-pixels.

14. The display panel according to claim 1,
wherein the non-display region further comprises an encapsulation region located at a side of the electrode contact region away from the display region; and
wherein the first dummy sub-pixels do not overlap with the encapsulation region in the direction perpendicular to the substrate.

15. The display panel according to claim 1, further comprising second dummy sub-pixels located at a same side of the substrate as the regular sub-pixels;
wherein the second dummy sub-pixels are located in the non-display region; at least a part of the second dummy sub-pixels overlaps with the electrode contact region in the direction perpendicular to the substrate;
wherein the regular sub-pixels comprise second-color sub-pixels, and the second-color sub-pixels comprise a second light-emitting material layer; and
wherein the second dummy sub-pixels comprise a same material as the second light-emitting material layer.

16. The display panel according to claim 15, wherein the first dummy sub-pixel at least partially overlaps with the second dummy sub-pixel in the electrode contact region.

17. The display panel according to claim 15, wherein the first-color sub-pixels are red sub-pixels and the second-color sub-pixels are green sub-pixels, or the first-color sub-pixels are green sub-pixels and the second-color sub-pixels are red sub-pixels.

18. The display panel according to claim 1, wherein the display panel further comprises an encapsulation region located at a side of the electrode contact region away from the display region.

19. The display panel according to claim 1,
wherein at least a part of an edge of the display region has an arc shape; or
wherein the display region has a circular or elliptical shape.

20. A display apparatus comprising a display panel defining a display region and a non-display region,
wherein the non-display region comprises an electrode contact region arranged along a direction surrounding the display region, and the display panel comprises:
a substrate;
first dummy sub-pixels and regular sub-pixels located at a same side of the substrate, wherein the first dummy sub-pixels comprise first edge dummy sub-pixels overlapping with the electrode contact region in a direction perpendicular to the substrate; the regular sub-pixels are located in the display region and comprise first-color sub-pixels; each of the regular sub-pixels comprises a first electrode, the first electrodes of the regular sub-pixels are connected to each other to form an electrode layer, and the electrode layer extends from the display region to the non-display region, and is in electrical contact with a contact metal layer in the electrode contact region; and
pixel circuits configured to drive the regular sub-pixels to emit light, wherein the pixel circuits do not overlap with the first dummy sub-pixels in the direction perpendicular to the substrate,
wherein the first-color sub-pixels each comprise a first light-emitting material layer, the first dummy sub-pixels comprise a same material as the first light-emitting material layer;
wherein in a direction parallel to the substrate, the first dummy sub-pixels are discontinuous with the first light-emitting material layer; and
wherein the electrode layer covers at least a part of the first edge dummy sub-pixels in the electrode contact region, and is in contact with the contact metal layer in at least a partial region other than the first edge dummy sub-pixels.
